(19) United States
(12) Patent Application Publication
(10) Pub. No.: US 2025/0318077 A1
(43) Pub. Date: Oct. 9, 2025

(54) IMMERSION COOLING ELECTRONIC SYSTEM

(71) Applicant: Wiwynn Corporation, New Taipei City (TW)

(72) Inventors: HSIEN-CHIEH HSIEH, New Taipei City (TW); Tsung-Han Li, New Taipei City (TW); Fu Sheng Cheng, New Taipei City (TW)

(21) Appl. No.: 19/093,353

(22) Filed: Mar. 28, 2025

Related U.S. Application Data
(60) Provisional application No. 63/573,589, filed on Apr. 3, 2024.
(60) Provisional application No. 63/717,960, filed on Nov. 8, 2024.

(30) Foreign Application Priority Data
Feb. 10, 2025 (TW) 114104876

(51) Int. Cl. H05K 7/20

(52) U.S. Cl. CPC H05K 7/20272; H05K 7/20236; H05K 7/20281; H05K 7/20763

(57) ABSTRACT

An immersion cooling electronic system includes a tank, a filtering pipeline and at least one filtering assembly. The tank has a fluid chamber, a first outlet, a second outlet and at least one inlet. The fluid chamber is configured to accommodate a coolant and has a main storage portion and a sub storage portion communicating with each other. The first outlet and the second outlet respectively communicate with the main storage portion and the sub storage portion, and the inlet communicates with the fluid chamber. One side of the filtering pipeline is connected to the first outlet and the second outlet, another side of the filtering pipeline is connected to the inlet, and at least parts of the filtering pipeline are connected in parallel. The filtering assembly is disposed on the filtering pipeline and includes at least one pump and a filtering device.

### CROSS-REFERENCE TO RELATED APPLICATIONS

This non-provisional application claims priority under 35 U.S.C. § 119(a) on Provisional Application No(s). 63/573,589 filed in U.S.A. on Apr. 3, 2024, Provisional Application No(s). 63/717,960 filed in U.S.A. on Nov. 8, 2024, and Patent Application No(s). 114104876 filed in Taiwan, R.O.C. on Feb. 10, 2025, the entire contents of which are hereby incorporated by reference.

### TECHNICAL FIELD

The disclosure relates to an immersion cooling electronic system.

### BACKGROUND

In order to efficiently and effectively dissipate heat from high-performance electronic devices, immersion liquid cooling technology has been adopted. This technique involves immersing electronic devices in a coolant filled in tank, allowing the coolant to absorb and remove heat generated by the electronic devices. However, as the density of electronic devices in the tank increases, the concentration of contaminants in the coolant also rises significantly. Therefore, it is necessary to rapidly reduce the concentration of contaminants to prevent any negative impact on the heat dissipation efficiency and the operation of the electronic devices.

### SUMMARY

One embodiment of the disclosure provides an immersion cooling electronic system. The immersion cooling electronic system includes a tank, a filtering pipeline and at least one filtering assembly. The tank has a fluid chamber, a first outlet, a second outlet and at least one inlet. The fluid chamber is configured to accommodate a coolant and has a main storage portion and a sub storage portion communicating with each other. The first outlet and the second outlet respectively communicate with the main storage portion and the sub storage portion, and the inlet communicates with the fluid chamber. One side of the filtering pipeline is connected to the first outlet and the second outlet, another side of the filtering pipeline is connected to the inlet, and at least parts of the filtering pipeline are connected in parallel. The filtering assembly is disposed on the filtering pipeline and includes at least one pump and a filtering device.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a block diagram of an immersion cooling electronic system according to some embodiments of the disclosure;

FIG. 2 is a schematic view of an immersion cooling electronic system according to some embodiments of the disclosure;

FIG. 3 is a block diagram of an immersion cooling electronic system according to some embodiments of the disclosure;

FIG. 4 is a block diagram of an immersion cooling electronic system according to some embodiments of the disclosure; and

FIG. 5 is a block diagram of an immersion cooling electronic system according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

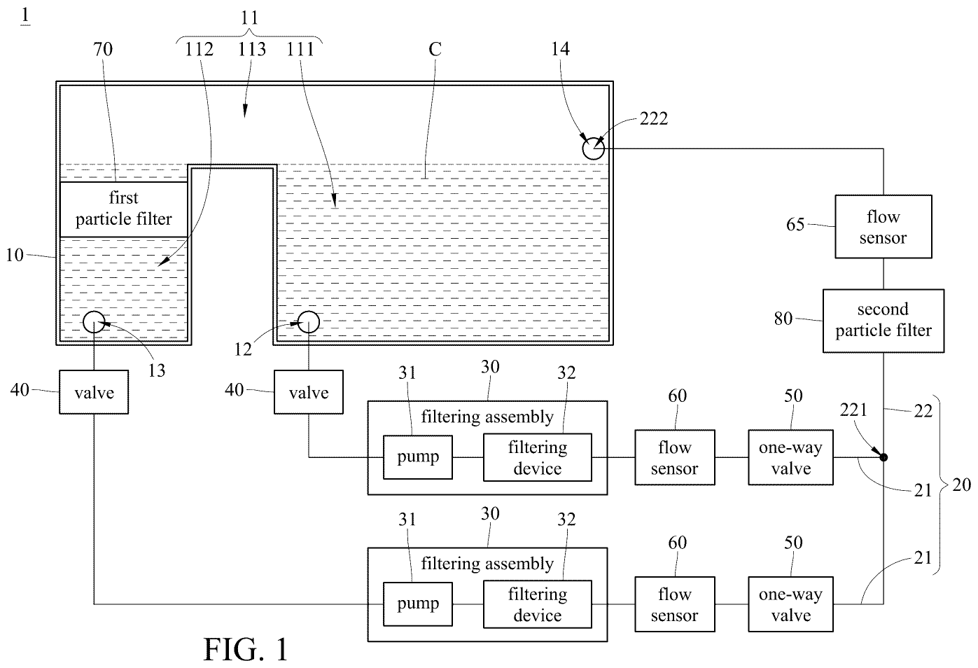

Referring to FIG. 1, FIG. 1 is a block diagram of an immersion cooling electronic system 1 according to some embodiments of the disclosure. The structural features of FIG. 1 can be applied to other embodiments of the disclosure.

The immersion cooling electronic system 1 includes a tank 10, a filtering pipeline 20 and at least one filtering assembly 30. The tank 10 has a fluid chamber 11, a first outlet 12, a second outlet 13 and at least one inlet 14. The fluid chamber 11 is configured to accommodate a coolant C, and the fluid chamber 11 has a main storage portion 111 and a sub storage portion 112 communicating with each other. The first outlet 12 and the second outlet 13 respectively communicate with the main storage portion 111 and the sub storage portion 112, and the inlet 14 communicates with the fluid chamber 11. One side of the filtering pipeline 20 is connected to the first outlet 12 and the second outlet 13, and another side of the filtering pipeline 20 is connected to the inlet 14. At least parts of the filtering pipeline 20 are connected in parallel. The filtering assembly 30 is disposed on the filtering pipeline 20, and the filtering assembly 30 includes at least one pump 31 and a filtering device 32. In some embodiments, the tank 10 is configured to accommodate at least one electronic device, such as a server. For example, the main storage portion 111 is configured to accommodate a plurality of servers (not shown). The servers may be vertically arranged in the main storage portion 111.

In some embodiments, the fluid chamber 11 may further have a communication portion 113. The main storage portion 111 and the sub storage portion 112 are spaced apart from each other. The communication portion 113 is a room located above the main storage portion 111 and the sub storage portion 112, and the communication portion 113 communicates with the main storage portion 111 and the sub storage portion 112. When a liquid level of the coolant C in the main storage portion 111 is higher than a side wall of the main storage portion 111 located closer to the sub storage portion 112, the coolant C overflows to the sub storage portion 112 through the communication portion 113.

Note that the communication portion 113 of the fluid chamber 11 is not restricted to be room located above the main storage portion 111 and the sub storage portion 112. In some other embodiments, the communication portion of the fluid chamber may be a channel located between the main storage portion and the sub storage portion.

In some embodiments, the first outlet 12 and the second outlet 13 may be respectively located at a bottom of the main storage portion 111 and a bottom of the sub storage portion 112.

In some embodiments, the pump 31 of the filtering assembly 30 is configured to drive the coolant C out of the first outlet 12 and the second outlet 13 of the tank 10 to flow towards the inlet 14 along the filtering pipeline 20. In some embodiments, the filtering device 32 is configured to remove chemical substances and moisture in the coolant C.

Note that at least parts of the filtering pipeline 20 being connected in parallel means that at least some parts of the filtering pipeline 20 are independent from each other. In some embodiments, the filtering pipeline 20 includes two branch parts 21 and a convergent part 22. Ends of the two branch parts 21 are respectively connected to the first outlet 12 and the second outlet 13, and other ends of the two branch parts 21 are connected to a convergent end 221 of the convergent part 22. An outlet end 222 of the convergent part 22 is connected to the inlet 14. In some embodiments, the immersion cooling electronic system 1 may include two filtering assemblies 30, and the two filtering assemblies 30 are respectively disposed on the two branch parts 21.

In some embodiments, the filtering device 32 of each of the two filtering assemblies 30 is located closer to the inlet 14 than the pump 31. In some embodiments, the filtering device 32 of each of the two filtering assemblies 30 is located closer to the convergent end 221 of the convergent part 22 than the pump 31. In other words, on each of the branch parts 21, the filtering device 32 of the filtering assembly 30 may be located in a downstream of the pump 31, but the disclosure is not limited thereto. In some other embodiments, on each of branch parts, the filtering device of the filtering assembly may be located in an upstream of the pump 31; that is, the filtering device of the filtering assembly may be located farther away from the convergent end of the convergent part than the pump.

In some embodiments, the immersion cooling electronic system 1 may further include two valves 40. The two valves 40 are respectively disposed on the two branch parts 21 of the filtering pipeline 20, and the two valves 40 are respectively located between the first outlet 12 and the pump 31 of one of the filtering assemblies 30 and between the second outlet 13 and the pump 31 of the other of the filtering assemblies 30. In other words, on the filtering pipeline 20, one of the valves 40 is located at a downstream of the first outlet 12 and an upstream of the pump 31 of one of the filtering assemblies 30, and the other of the valves 40 is located at a downstream of the second outlet 13 and the pump 31 of the other of the filtering assemblies 30. The two valves 40 are respectively configured to open or close the two branch parts 21.

In some embodiments, the immersion cooling electronic system 1 may further include two one-way valves 50. The two one-way valves 50 are respectively disposed on the two branch parts 21, and the two one-way valves 50 are respectively located closer to the convergent end 221 of the convergent part 22 than the filtering device 32 of each of the two filtering assemblies 30. In other words, on each of the branch parts 21, the one-way valve 50 may be located at a downstream of the filtering device 32. The two one-way valves 50 respectively merely enable the coolant C to flow from upstream to downstream instead of flowing from downstream to upstream.

In some embodiments, the immersion cooling electronic system 1 may further include two flow sensors 60. The two flow sensors 60 are respectively disposed on the two branch parts 21 for measuring flow rates of the coolant C in the two branch parts 21.

In some embodiments, the two flow sensors 60 are respectively located closer to the convergent end 221 of the convergent part 22 than the filtering device 32 of each of the two filtering assemblies 30. In other words, on each of the branch parts 21, the flow sensor 60 may be located at a downstream of the filtering device 32. In some embodiments, the two one-way valves 50 may be respectively located closer to the convergent end 221 of the convergent part 22 than the two flow sensors 60. In other words, on each of the branch parts 21, the one-way valve 50 may be located at a downstream of the flow sensor 60.

In some embodiments, the immersion cooling electronic system 1 may further include another flow sensor 65. The flow sensor 65 is disposed on the convergent part 22 for measuring a flow rate of the coolant C in the convergent part 22.

In some embodiments, the immersion cooling electronic system 1 may further include a first particle filter 70. The first particle filter 70 is disposed in the sub storage portion 112. In one embodiment, the immersion cooling electronic system 1 may further include a second particle filter 80. The second particle filter 80 is disposed on the filtering pipeline 20 and is located closer to the inlet 14 than the filtering assemblies 30. In other words, on the filtering pipeline 20, the second particle filter 80 is located at a downstream of the filtering assemblies 30. In some embodiments, the second particle filter 80 is disposed on the convergent part 22 of the filtering pipeline 20, and the second particle filter 80 is located closer to the convergent end 221 of the convergent part 22 than the flow sensor 65. In other words, on the convergent part 22, the second particle filter 80 may be located at an upstream of the flow sensor 65.

In some embodiments, the first particle filter 70 and the second particle filter 80 are configured to remove different sizes of particles in the coolant C. In some embodiments, a pore size of the first particle filter 70 is greater than a pore size of the second particle filter 80. The first particle filter 70 can filter larger particle in the coolant C overflowing from the main storage portion 111 to the sub storage portion 112. The second particle filter 80 can filter smaller particles in the coolant C in the filtering pipeline 20.

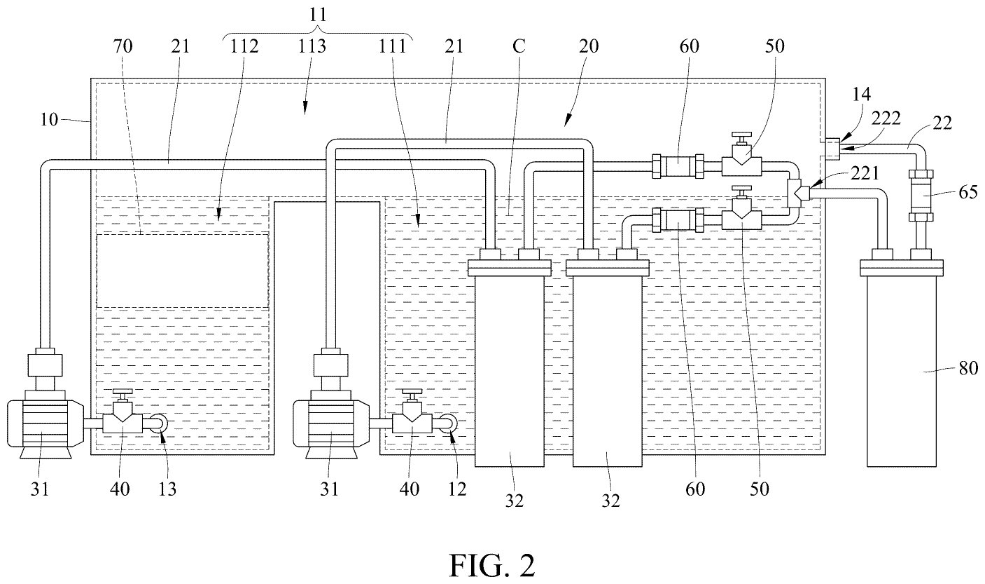

Then, referring to FIG. 2, FIG. 2 is a schematic view of the immersion cooling electronic system 1 according to some embodiments of the disclosure. The structural features of FIG. 2 can be applied to other embodiments of the disclosure.

In some embodiments, a part of the filtering pipeline 20 located at an upstream of the filtering device 32 is at least partially higher than the liquid level of the coolant C in the fluid chamber 11. In some embodiments, a part of the filtering pipeline 20 located between the filtering device 32 and the pump 31 is at least partially higher than the liquid level of the coolant C in the fluid chamber 11. In other words, a part of each of the branch parts 21 located between the filtering device 32 and the pump 31 is at least partially higher than the liquid level of the coolant C in the fluid chamber 11. In other words, a part of each of the branch parts 21 located at the upstream of the filtering device 32 and the downstream of the pump 31 is at least partially higher than the liquid level of the coolant C in the fluid chamber 11.

During the operation of the immersion cooling electronic system 1, the two valves 40 open the two branch parts 21. Under the operation of the pumps 31 of the filtering assemblies 30, the coolant C flowing out from the first outlet 12 and the second outlet 13 to the two branch parts 21 passes through the filtering devices 32 and is filtered by the filtering devices 32. Then, the coolant C flows through the one-way valves 50 on the branch parts 21 and converges at the convergent end 221 of the convergent part 22. After that, the coolant C flows through the second particle filter 80 and then enters the fluid chamber 11 through the inlet 14.

In the aforementioned embodiments, the first outlet 12 and the second outlet 13 of the tank 10 respectively communicate with the main storage portion 111 and the sub storage portion 112 of the fluid chamber 11, the inlet 14 communicates with the fluid chamber 11, one side of the filtering pipeline 20 is connected to the first outlet 12 and the second outlet 13, another side of the filtering pipeline 20 is connected to the inlet 14, at least parts of the filtering pipeline 20 are connected in parallel, and the filtering assemblies 30 are disposed on the filtering pipeline 20 and each includes the pump 31 and the filtering device 32. The above configuration allows the coolant C to flow from the tank 10 to the filtering pipeline 20 to be filtered by the filtering devices 32, and then return to the tank 10 to continue absorbing heat generated by the electronic device. In this way, the concentration of contaminants in the coolant C can be reduced as soon as possible, preventing contaminants from affecting the heat dissipation efficiency and causing negative impacts on the operation of the electronic device.

In the aforementioned embodiments, the filtering assemblies 30 are disposed outside the tank 10, and thus the sizes of the pumps 31 and the filtering devices 32 of the filtering assemblies 30 are not limited by the fluid chamber 11 of the tank 10. In addition, when the pumps 31 and the filtering devices 32 of the filtering assemblies 30 are required to be maintained, there is no need to open the tank 10, thereby easily performing the maintenances of the pumps 31 and the filtering devices 32 and reducing the possibility of the dissipation of the coolant C. Moreover, a user can choose more powerful pumps 31. Furthermore, since the pumps 31 are not immersed in the coolant C in the tank 10, the coolant C is prevented from being contaminated by the pumps 31.

In the aforementioned embodiments, the downstream of each of the filtering devices 32 is provided with the flow sensor 60, and the downstream of the second particle filter 80 is provided with the flow sensor 65, which helps to determine whether the filtering devices 32 and the second particle filter 80 are stuck or have abnormal situations according to the flow rates measured by the flow sensors 60 and 65, thereby enabling the user to determine whether maintenance is required.

Note that the flow sensors 60 and 65 are optional components. In some other embodiments, the flow sensor disposed on the convergent part may be omitted, or the flow sensors disposed on the branch parts may be omitted.

In the aforementioned embodiments, a part of the filtering pipeline 20 located between the filtering device 32 and the pump 31 is at least partially higher than the liquid level of the coolant C in the fluid chamber 11, which can prevent the coolant C from flowing into the filtering device 32 by gravity when the pump 31 stops operating. This ensures that the coolant C is only actively pumped through the filtering device 32 during the operation of the pump 31, thus ensuring the filtering efficiency.

Note that a part of the filtering pipeline 20 located between the filtering device 32 and the pump 31 is not restricted to being at least partially higher than the liquid level of the coolant C in the fluid chamber 11. In some other embodiments, a part of the filtering pipeline located at the upstream of the pump may be at least partially higher than the liquid level of the coolant in the fluid chamber. In another embodiment, whole part of the filtering pipeline located at the upstream of the filtering device may not be higher than the liquid level of the coolant in the fluid chamber. In such a case, when the pumps stop operating, the branch parts may be closed by the two valves merely for preventing the coolant from entering the filtering devices. In still another embodiment, the valves may be omitted while a part of the filtering pipeline located at the upstream of the filtering device may be maintained to be at least partially higher than the liquid level of the coolant in the fluid chamber.

In the aforementioned embodiments, when one of the pumps 31 stops operating and the other pump 31 remains in operation, the arrangement of the two one-way valves 50 can prevent the coolant C from flowing from the branch part 21 with the operating pump 31 through the convergent end 221 of the convergent part 22 into the branch part 21 with the non-operating pump 31. This prevents the coolant C from contacting the filtering device 32 in the branch part 21 with the non-operating pump 31.

Note that the one-way valves 50 are optional components and may be omitted in some other embodiments.

In the aforementioned embodiments, the first outlet 12 and the second outlet 13 of the tank 10 are respectively located at the bottom of the main storage portion 111 and the bottom of the sub storage portion 112. This arrangement allows impurity particles at the bottom of the main storage portion 111 and the bottom of the sub storage portion 112 to easily enter the filtering pipeline 20 and then are removed by the second particle filter 80.

Note that the first particle filter 70 and the second particle filter 80 are optional components. In some other embodiments, the first particle filter and/or the second particle filter may be omitted in the immersion cooling electronic system, or the particle filters may be integrated in the filtering devices, that is, the filtering devices not only remove chemical substances and moisture, but also remove particles.

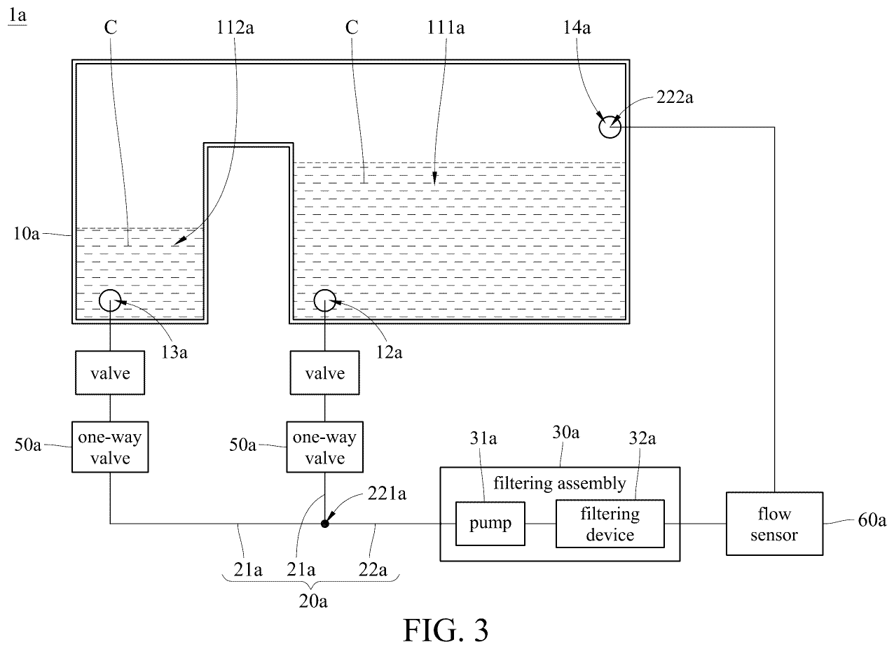

Then, referring to FIG. 3, FIG. 3 is a block diagram of an immersion cooling electronic system la according to some embodiments of the disclosure. The structural features of FIG. 3 can be applied to other embodiments of the disclosure.

The immersion cooling electronic system la shown in FIG. 3 is similar to the immersion cooling electronic system 1 shown in FIG. 1, and the following paragraphs mainly introduce the differences between them while the same parts between them will not be repeated introduced hereinafter.

In the embodiment of FIG. 3, a filtering pipeline 20a includes two branch parts 21a and a convergent part 22a. Ends of the two branch parts 21a are respectively connected to first outlet 12a and a second outlet 13a of a tank 10a, and other ends of the branch parts 21a are connected to a convergent end 221a of the convergent part 22a. An outlet end 222a of the convergent part 22a is connected to an inlet 14a of the tank 10a. The immersion cooling electronic system 1 includes a single filtering assembly 30a, and the filtering assembly 30a is disposed on the convergent part 22a. In some embodiments, a pump 31a of the filtering assembly 30a is located closer to the convergent end 221a of the convergent part 22a than a filtering device 32a of the filtering assembly 30a; that is, on the convergent part 22a, the pump 31a is located at an upstream of the filtering device 32a.

In the embodiment of FIG. 3, the immersion cooling electronic system la includes a single flow sensor 60a. The flow sensor 60a is disposed on the convergent part 22a. In some embodiments, the flow sensor 60a is located closer to the outlet end 222a of the convergent part 22a than the filtering assembly 30a; that is, on the convergent part 22a, the flow sensor 60a is located at a downstream of the filtering assembly 30a.

In the embodiment of FIG. 3, the immersion cooling electronic system 1a includes two one-way valves 50a. The two one-way valves 50a are respectively disposed on the two branch parts 21a, and the two one-way valves 50a are respectively located between the first outlet 12a of the tank 10a and the pump 31a and between the second outlet 13a of the tank 10a and the pump 31a; that is, on the filtering pipeline 20a, one of the one-way valves 50a is located at a downstream of the first outlet 12a and an upstream of the pump 31a, and the other of the one-way valves 50a is located at a downstream of the second outlet 13a and the upstream of the pump 31a.

In the embodiment of FIG. 3, the positions of the two one-way valves 50a can prevent a main storage portion 111a and a sub storage portion 112a of the tank 10a from forming a communicating tubes via the convergent end 221a of the convergent part 22a. As result, the liquid levels of the coolant C in the main storage portion 111a and the sub storage portion 112a can be different heights.

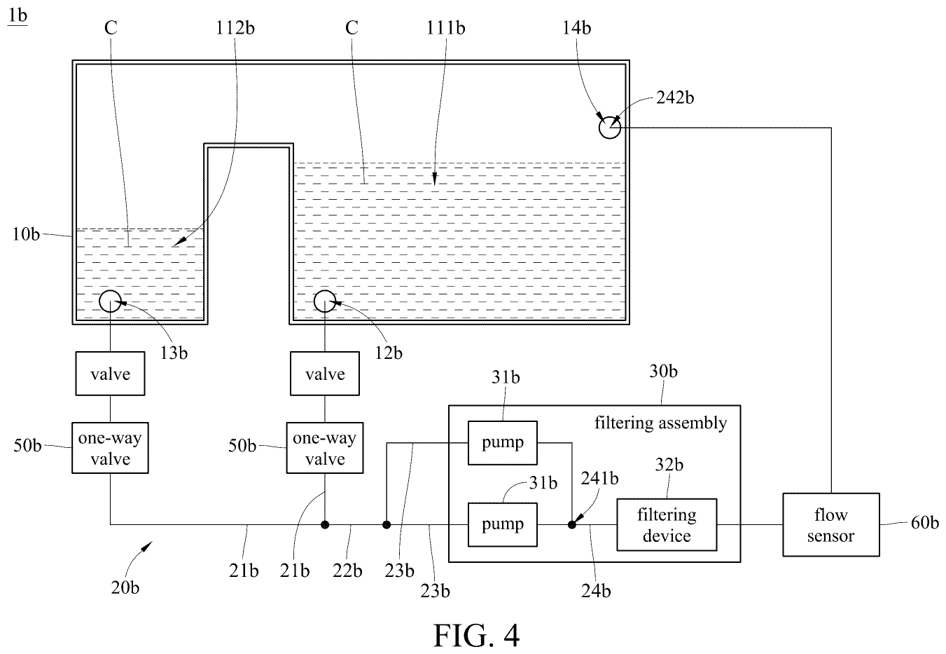

Then, referring to FIG. 4, FIG. 4 is a block diagram of an immersion cooling electronic system 1b according to some embodiments of the disclosure. The structural features of FIG. 4 can be applied to other embodiments of the disclosure.

The immersion cooling electronic system 1b shown in FIG. 4 is similar to the immersion cooling electronic system 1 shown in FIG. 1, and the following paragraphs mainly introduce the differences between them while the same parts between them will not be repeated introduced hereinafter.

In the embodiment of FIG. 4, a filtering pipeline 20b includes two first branch parts 21b, a first convergent part 22b, two second branch parts 23b and a second convergent part 24b. Ends of the two first branch parts 21b are respectively connected to a first outlet 12b and a second outlet 13b of a tank 10b, and other ends of the two first branch parts 21b are connected to ends of the two second branch parts 23b via the first convergent part 22b. Other ends of the two second branch parts 23b are connected to a convergent end 241b of the second convergent part 24b, and an outlet end 242b of the second convergent part 24b is connected to an inlet 14b of the tank 10b. The immersion cooling electronic system 1b includes a single filtering assembly 30b, and the filtering assembly 30b includes two pumps 31b and a filtering device 32b. The two pumps 31b are respectively disposed on the two second branch parts 23b, and the filtering device 32b is disposed on the second convergent part 24b.

In the embodiment of FIG. 4, the immersion cooling electronic system 1b includes a single flow sensor 60b. The flow sensor 60b is disposed on the second convergent part 24b. In some embodiments, the flow sensor 60b is located closer to the outlet end 242b of the second convergent part 24b than the filtering device 32b; that is, on the filtering pipeline 20, the flow sensor 60b is located at a downstream of the filtering device 32b.

In the embodiment of FIG. 4, the immersion cooling electronic system 1b includes two one-way valves 50b. The two one-way valves 50b are respectively disposed on the two first branch parts 21b, and the two one-way valves 50b are respectively located between the first outlet 12b of the tank 10b and the pumps 31b and between the second outlet 13b of the tank 10b and the pumps 31b; that is, on the filtering pipeline 20b, one of the one-way valves 50b is located at a downstream of the first outlet 12b and an upstream of the pump 31b, and the other of the one-way valves 50b is located at a downstream of the second outlet 13b and the upstream of the pumps 31b.

In the embodiment of FIG. 4, the positions of the two one-way valves 50b can prevent a main storage portion 111b and a sub storage portion 112b of the tank 10b from forming a communicating tubes via the first convergent part 22b. As result, the liquid levels of the coolant C in the main storage portion 111b and the sub storage portion 112b can be different heights.

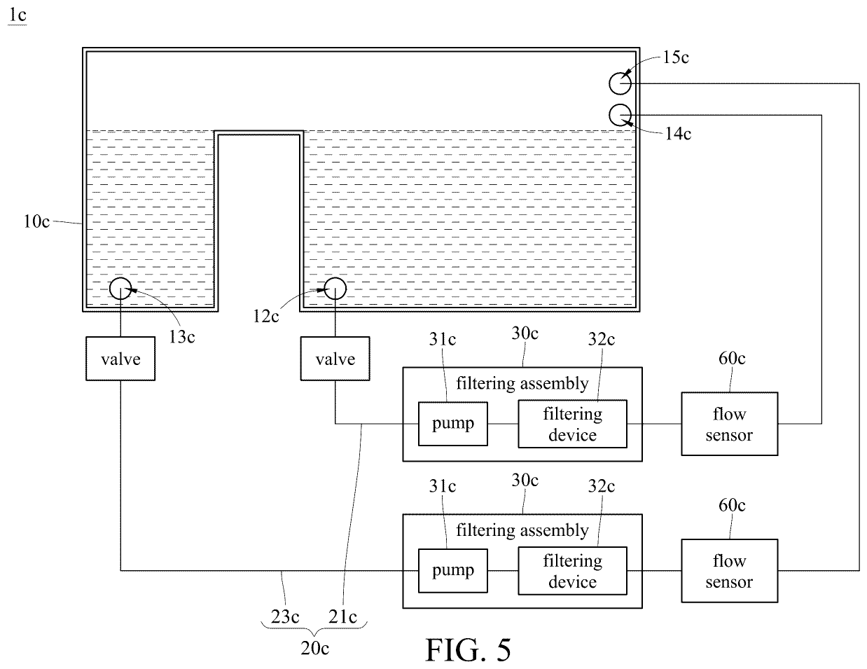

Then, referring to FIG. 5, FIG. 5 is a block diagram of an immersion cooling electronic system 1c according to some embodiments of the disclosure. The structural features of FIG. 5 can be applied to other embodiments of the disclosure.

The immersion cooling electronic system 1c shown in FIG. 5 is similar to the immersion cooling electronic system 1 shown in FIG. 1, and the following paragraphs mainly introduce the differences between them while the same parts between them will not be repeated introduced hereinafter.

In the embodiment of FIG. 5, a tank 10c has a first inlet 14c and a second inlet 15c. A filtering pipeline 20c includes a first branch part 21c and a second branch part 23c. The first branch part 21c and the second branch part 23c are entirely connected in parallel. The first branch part 21c is connected to the first outlet 12c and the first inlet 14c of the tank 10c, and the second branch part 23c is connected to the second outlet 13c and the second inlet 15c of the tank 10c. In other words, the first branch part 21c and the second branch part 23c are independent from each other and does not converge. The immersion cooling electronic system 1c includes two filtering assemblies 30c, and the filtering assemblies 30c are respectively disposed on the first branch part 21c and the second branch part 23c. In one of the filtering assemblies 30c, a pump 31c is located closer to the first outlet 12c than a filtering device 32c. In the other of the filtering assemblies 30c, a pump 31c is located closer to the second outlet 13c than a filtering device 32c. In other words, on the first branch part 21c, the pump 31c is located at an upstream of the filtering device 32c; on the second branch part 23c, the pump 31c is located at an upstream of the filtering device 32c.

In the embodiment of FIG. 5, the immersion cooling electronic system 1 includes two flow sensors 60c. The two flow sensors 60c are respectively disposed on the first branch part 21c and the second branch part 23c. In one embodiment, the two flow sensors 60c are respectively located closer to the first inlet 14c and the second inlet 15c than the two filtering assemblies 30. In other words, on the first branch part 21c, the flow sensor 60c is located at a downstream of the filtering assembly 30c; on the second branch part 23c, the flow sensor 60c is located at a downstream of the filtering assembly 30c.

According to the immersion cooling electronic systems as disclosed in the above embodiments, the first outlet and the second outlet of the tank respectively communicate with the main storage portion and the sub storage portion of the fluid chamber, the inlet communicates with the fluid chamber, one side of the filtering pipeline is connected to the first outlet and the second outlet, another side of the filtering pipeline is connected to the inlet, at least parts of the filtering pipeline are connected in parallel, and the filtering assemblies are disposed on the filtering pipeline and each includes the pump and the filtering device. The above configuration allows the coolant to flow from the tank to the filtering pipeline to be filtered by the filtering devices, and then return to the tank to continue absorbing heat generated by the electronic device. In this way, the concentration of contaminants in the coolant can be reduced as soon as possible, preventing contaminants from affecting the heat dissipation efficiency and causing negative impacts on the operation of the electronic device.

In addition, the filtering assemblies are disposed outside the tank, and thus the sizes of the pumps and the filtering devices of the filtering assemblies are not limited by the fluid chamber of the tank. In addition, when the pumps and the filtering devices of the filtering assemblies are required to be maintained, there is no need to open the tank, thereby easily performing the maintenances of the pumps and the filtering devices and reducing the possibility of the dissipation of the coolant. Moreover, a user can choose more powerful pumps. Furthermore, since the pumps are not immersed in the coolant in the tank, the coolant is prevented from being contaminated by the pumps.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. An immersion cooling electronic system, comprising:
a tank, having a fluid chamber, a first outlet, a second outlet and at least one inlet, wherein the fluid chamber is configured to accommodate a coolant and has a main storage portion and a sub storage portion communicating with each other, the first outlet and the second outlet respectively communicate with the main storage portion and the sub storage portion, and the at least one inlet communicates with the fluid chamber;
a filtering pipeline, wherein one side of the filtering pipeline is connected to the first outlet and the second outlet, another side of the filtering pipeline is connected to the at least one inlet, and at least parts of the filtering pipeline are connected in parallel; and
at least one filtering assembly, disposed on the filtering pipeline and comprising at least one pump and a filtering device.

2. The immersion cooling electronic system according to claim 1, wherein the filtering pipeline comprises two branch parts and a convergent part, ends of the two branch parts are respectively connected to the first outlet and the second outlet, other ends of the two branch parts are connected to a convergent end of the convergent part, an outlet end of the convergent part is connected to the at least one inlet, the at least one filtering assembly comprises two filtering assemblies, and the two filtering assemblies are respectively disposed on the two branch parts.

3. The immersion cooling electronic system according to claim 2, further comprising two one-way valves, wherein the two one-way valves are respectively disposed on the two branch parts, and the two one-way valves are located closer to the convergent end of the convergent part than the filtering device of each of the two filtering assemblies.

4. The immersion cooling electronic system according to claim 2, further comprising two flow sensors, wherein the two flow sensors are respectively disposed on the two branch parts.

5. The immersion cooling electronic system according to claim 4, wherein the two flow sensors are located closer to the convergent end of the convergent part than the filtering device of each of the two filtering assemblies.

6. The immersion cooling electronic system according to claim 2, further comprising a flow sensor, wherein the flow sensor is disposed on the convergent part.

7. The immersion cooling electronic system according to claim 1, wherein the filtering pipeline comprises two branch parts and a convergent part, ends of the two branch parts are respectively connected to the first outlet and the second outlet, other ends of the two branch parts are connected to a convergent end of the convergent part, an outlet end of the convergent part is connected to the at least one inlet, and the at least one filtering assembly is disposed on the convergent part.

8. The immersion cooling electronic system according to claim 7, further comprising a flow sensor, wherein the flow sensor is disposed on the convergent part.

9. The immersion cooling electronic system according to claim 8, wherein the flow sensor is located closer to the outlet end than the at least one filtering assembly.

10. The immersion cooling electronic system according to claim 1, wherein the filtering pipeline comprises two first branch parts, a first convergent part, two second branch parts and a second convergent part, ends of the two first branch parts are respectively connected to the first outlet and the second outlet, other ends of the two first branch parts are connected to ends of the two second branch parts via the first convergent part, other ends of the two second branch parts are connected to a convergent end of the second convergent part, an outlet end of the second convergent part is connected to the at least one inlet, the at least one pump comprises two pumps, the two pumps are respectively disposed on the two second branch parts, and the filtering device is disposed on the second convergent part.

11. The immersion cooling electronic system according to claim 10, further comprising a flow sensor, wherein the flow sensor is disposed on the second convergent part.

12. The immersion cooling electronic system according to claim 11, wherein the flow sensor is located closer to the outlet end than the filtering device.

13. The immersion cooling electronic system according to claim 1, wherein the at least one inlet comprises a first inlet and a second inlet, the filtering pipeline comprises a first branch part and a second branch part, the first branch part and the second branch part are entirely connected in parallel, the first branch part is connected to the first outlet and the first inlet, the second branch part is connected to the second outlet and the second inlet, the at least one filtering assembly comprises two filtering assemblies, and the two filtering assemblies are respectively disposed on the first branch part and the second branch part.

14. The immersion cooling electronic system according to claim 13, further comprising two flow sensors, wherein the two flow sensors are respectively disposed on the first branch part and the second branch part.

15. The immersion cooling electronic system according to claim 14, wherein the two flow sensors are respectively located closer to the first inlet and the second inlet than the two filtering assemblies.

16. The immersion cooling electronic system according to claim 1, further comprising a first particle filter, wherein the first particle filter is disposed in the sub storage portion.

17. The immersion cooling electronic system according to claim 16, further comprising a second particle filter, wherein the second particle filter is disposed on the filtering pipeline and located closer to the at least one inlet than the at least one filtering assembly.

18. The immersion cooling electronic system according to claim 17, wherein a pore size of the first particle filter is greater than a pore size of the second particle filter.

19. The immersion cooling electronic system according to claim 1, wherein the filtering device is located closer to the at least one inlet than the at least one pump, and a part of the filtering pipeline located at an upstream of the filtering device is at least partially higher than a liquid level of the coolant in the fluid chamber.

20. The immersion cooling electronic system according to claim 19, wherein a part of the filtering pipeline located between the filtering device and the at least one pump is at least partially higher than the liquid level of the coolant in the fluid chamber.

21. The immersion cooling electronic system according to claim 1, further comprising two valves, wherein the two valves are disposed on the filtering pipeline, and the two valves are respectively located between the first outlet and the at least one pump and between the second outlet and the at least one pump.

22. The immersion cooling electronic system according to claim 1, wherein the fluid chamber further has a communication portion, the main storage portion and the sub storage portion are spaced apart from each other, the communication portion is located above the main storage portion and the sub storage portion and communicates with the main storage portion and the sub storage portion.

23. The immersion cooling electronic system according to claim 1, wherein the first outlet and the second outlet are respectively located at a bottom of the main storage portion and a bottom of the sub storage portion.

24. The immersion cooling electronic system according to claim 1, further comprising two one-way valves, wherein the two one-way valves are disposed on the filtering pipeline, and the two one-way valves are respectively located between the first outlet and the at least one pump and between the second outlet and the at least one pump.
